(19) United States
(12) Patent Application Publication
(10) Pub. No.: US 2007/0148846 A1
(43) Pub. Date: Jun. 28, 2007

(54) Image Sensor and Method of Manufacturing the Same

(76) Inventor: Woo Seok Hyun, Seo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/611,260

(22) Filed: Dec. 15, 2006

(30) Foreign Application Priority Data
Dec. 28, 2005 (KR) 10-2005-0132367

(51) Int. Cl. H01L 21/8238

(52) U.S. Cl. 438/199

(57) ABSTRACT

A CMOS image sensor and a method of manufacturing the same are provided. The CMOS image sensor includes a semiconductor substrate including a plurality of photodiodes and a plurality of transistors, a first interlayer dielectric formed on the semiconductor substrate, a metal wiring and a second interlayer dielectric formed on the first interlayer dielectric, a plurality of color filter layers formed in the trenches formed in the second interlayer dielectric, and a plurality of micro lenses formed on the plurality of the color filter layers.

### RELATED APPLICATION(S)

This application claims the benefit under 35 U.S.C. § 119(e) of Korean Patent Application No. 10-2005-0132367 filed Dec. 28, 2005, which is incorporated herein by reference in its entirety.

### FIELD OF THE INVENTION

The present invention relates to an image sensor and a method of manufacturing the same.

### BACKGROUND OF THE INVENTION

An image sensor is a semiconductor device for converting an optical image into electrical signals, and a CCD (charge coupled device) is a type of semiconductor device in which individual MOS (Metal-Oxide-Silicon) capacitors are very closely positioned to each other and charge carriers are stored in the capacitor and transferred.

A complimentary metal oxide semiconductor (CMOS) image sensor is a device that employs a switching mode to sequentially detect an output by providing MOS transistors corresponding to the number of pixels through a CMOS technology that uses peripheral devices, such as a control circuit and a signal processing circuit.

CCDs have a complicated driving manner and high power consumption while requiring multi-step mask processes, so the manufacturing of CCDs is complicated. Moreover, the signal processing circuit cannot be realized within a single CCD chip. Recently, research has been conducted on developing a CMOS image sensor utilizing sub-micron CMOS technology to overcome the defects of CCDs.

A CMOS image sensor realizes an image by sequentially detecting signals by means of a switching mode through forming a photodiode and a MOS transistor within a unit pixel.

Since the CMOS image sensor is manufactured by using the CMOS manufacturing technology, the power consumption is small and the number of required masks is about 20, compared with a CCD manufacturing process requiring about 30-40 masks. In addition, a CMOS image sensor can be formed as a device in one chip including various signal processing circuits. Thus, CMOS image sensors have been spotlighted as the next generation image sensors and can be applied to various fields including DSCs (digital still cameras), PC cameras, and mobile cameras.

The CMOS image sensor can be classified as a 3T type CMOS image sensor, a 4T type CMOS image sensor, or a 5T type CMOS image sensor, according to the number of the transistors formed in a unit pixel. The 3T type CMOS image sensor includes one photodiode and three transistors, and the 4T type CMOS image sensor includes one photodiode and four transistors. A description of the lay-out of a unit pixel of the 3T type CMOS image sensor follows.

FIG. 1 is an equivalent circuit diagram of the conventional 3T type CMOS image sensor, and FIG. 2 is a lay-out of a unit pixel of the conventional 3T type CMOS image sensor.

Referring to FIG. 1, the unit pixel of the 3T type CMOS image sensor includes one photodiode PD and three nMOS transistors T1, T2 and T3. The cathode of the photodiode PD is connected to the drain of the first nMOS transistor T1 and the gate of the second nMOS transistor T2.

The sources of the first and second NMOS transistors T1 and T2 are connected to a standard voltage VR supplying an electric source line. The gate of the first NMOS transistor T1 is connected to a reset signal RST supplying reset line.

The source of the third NMOS transistor T3 is connected to the drain of the second nMOS transistor, and the drain of the third nMOS transistor T3 is connected to a reading circuit (not shown in the drawings) through a signal line. The gate of the third NMOS transistor T3 is connected to a thermal selecting line to which a select signal (SLCT) is supplied.

Therefore, the first NMOS transistor T1 is called a reset transistor Rx, the second nMOS transistor T2 is called a drive transistor Dx, and the third NMOS transistor T3 is called a select transistor Sx.

Referring to FIG. 2, a unit pixel of the 3T type CMOS image sensor includes one photodiode 20 formed at a wide portion of an active area 10 among the defined active area 10, and three gate electrodes of transistor 120, 130 and 140 formed while overlapping the remaining active area 10.

That is, a reset transistor Rx is formed by the first gate electrode 120, a drive transistor Dx is formed by the second gate electrode 130, and a select transistor Sx is formed by the third gate electrode.

Impurity ions are implanted onto the active area 10 of each transistor to form a source/drain region on each transistor.

A power source voltage Vdd is applied to the source/drain region between the reset transistor Rx and the drive transistor Dx. The source/drain region at one side of the select transistor Sx is connected to a reading circuit.

The gate electrodes 120, 130 and 140 are connected to each signal line, and the signal line includes a pad at one terminal to be connected to an exterior driving circuit.

FIG. 3 is a cross-sectional view of the conventional CMOS image sensor.

Referring to FIG. 3, a p− type epitaxial layer 101 is shown on a p++ type semiconductor substrate 100, which has an isolation region and an active area (a photodiode region and a transistor region) defined. A field oxide layer 102 is formed on the isolation region for isolating regions corresponding to input regions of green light, red light and blue light. An n− type diffusion region 103 is formed at the photodiode region of the semiconductor substrate 100.

A gate electrode 105 is formed on the transistor region of the semiconductor substrate 100 with a gate insulating layer 104 formed there between. Also, insulating layer sidewalls 106 are formed at both side walls of the gate electrode 105.

A first interlayer dielectric 108 is formed on the semiconductor substrate 100 including the gate electrode 105, and various metal wirings 109 are formed with a predetermined interval on the first interlayer dielectric 108.

A second interlayer dielectric 110 is formed to a thickness of about 4000 Å on the semiconductor substrate 100 including the metal wiring 109, and a nitride layer 111 is formed on the second interlayer dielectric 110. A color filter layer 112 of red (R), green (G) and blue (B) color filters corresponding to each n− type diffusion region 103 is formed on the nitride layer 111.

A planarizing layer 113 is formed on the semiconductor substrate 100, including each color filter layer 112. Also, a microlens 114 is formed on the planarizing layer 113 corresponding to each color filter layer 112.

Reference number 107 represents an impurity region of the source and drain.

The above-described CMOS image sensor includes a color filter layer 112 formed on a plurality of interlayer dielectrics and a nitride layer. It also includes a planarizing layer 113 formed on the substrate including the color filter layer 112 and a microlens formed on the planarizing layer 113. The focal distance from the microlens 114 to the photodiode region is lengthened due to the many layers between the micro-lens 114 and the photodiode region. Therefore, cross-talk between neighboring pixels and a reduction of the photo-sensitivity may occur.

### BRIEF SUMMARY

An object of embodiments the present invention is to provide a CMOS image sensor of which cross-talk between neighboring pixels can be minimized or prevented and of which sensitivity can be improved by reducing the distance from a microlens to a photodiode region and a method of manufacturing the same.

Accordingly, there is provided a CMOS image sensor comprising a semiconductor substrate including a plurality of photodiodes and a plurality of transistors, a first interlayer dielectric formed on the semiconductor substrate, a metal wiring and a second interlayer dielectric formed on the first interlayer dielectric, a plurality of color filter layers formed on the second interlayer dielectric and a plurality of micro lenses formed on the plurality of color filter layers.

There is also provided a CMOS image sensor comprising: a semiconductor substrate including a plurality of photodiodes and a plurality of transistors; a first interlayer dielectric formed on the semiconductor substrate; a metal wiring; a plurality of color filter layers and a second interlayer dielectric formed on the first interlayer dielectric; and a plurality of micro lenses formed on the plurality of the color filter layers.

There is also provided a method of manufacturing a CMOS image sensor comprising the steps: of forming a plurality of photodiodes and a plurality of transistors on a semiconductor substrate; forming a first interlayer dielectric on the semiconductor substrate including the plurality of the photodiodes and the plurality of the transistors; forming a metal wiring on the first interlayer dielectric; forming a second interlayer dielectric on the first interlayer dielectric and the metal wiring; forming a trench in the second interlayer dielectric; forming a plurality of color filter layers in the trench; and forming a plurality of micro lenses on the plurality of the color filter layers.

### BRIEF DESCRIPTION OF THE DRAWINGS

FIG. 1 is an equivalent circuit diagram of the conventional 3T type CMOS image sensor.

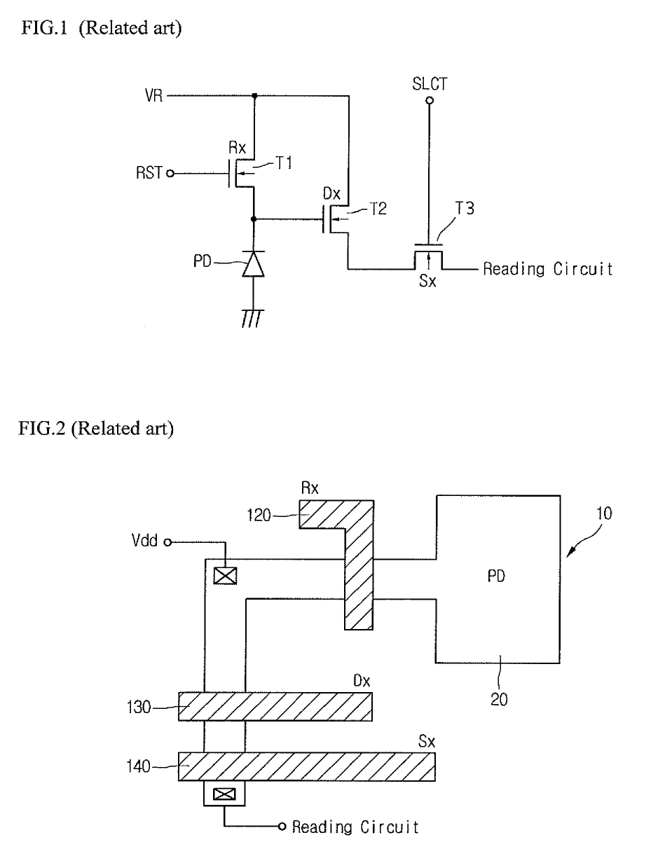

FIG. 2 is a lay-out illustrating a unit pixel of the conventional 3T type CMOS image sensor.

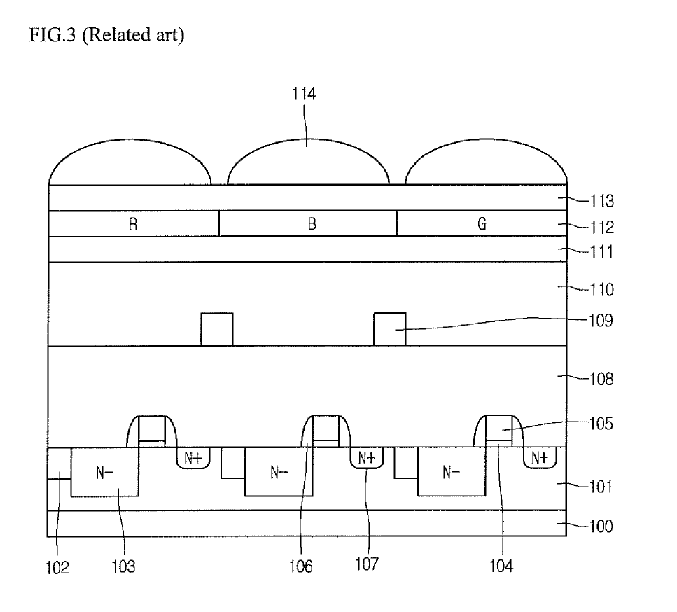

FIG. 3 is a cross-sectional view of the conventional CMOS image sensor.

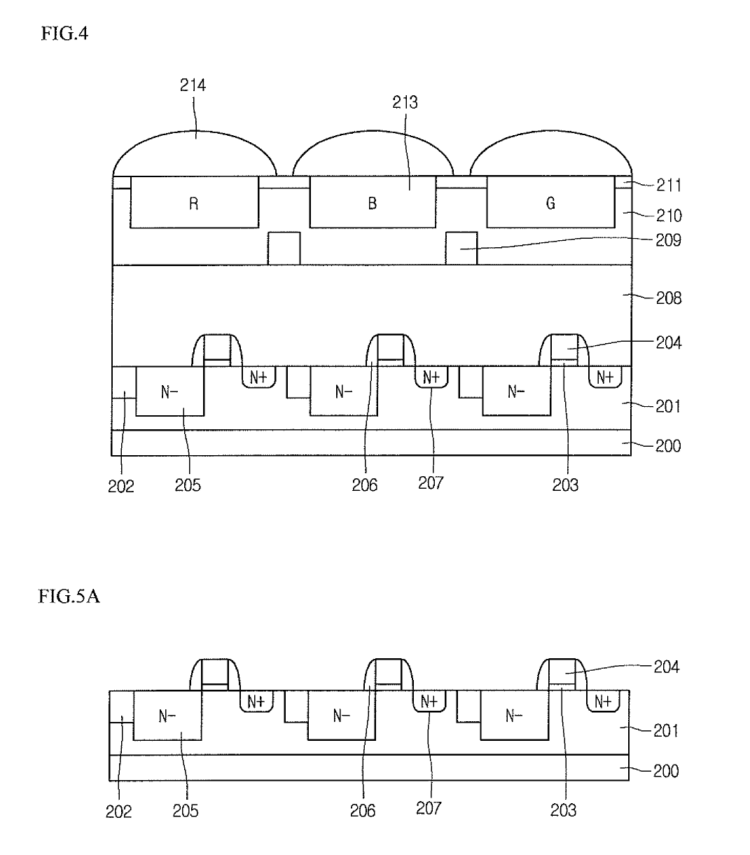

FIG. 4 is a cross-sectional view of a CMOS image sensor according to an embodiment of the present invention.

FIGS. 5A & 5B are cross-sectional views illustrating a method of manufacturing a CMOS image sensor according to an embodiment of the present invention.

FIG. 6 is a cross-sectional view of a CMOS image sensor according to another embodiment of the present invention.

### DETAILED DESCRIPTION OF THE INVENTION

Hereinafter, a CMOS image sensor and a method of manufacturing the same according to preferred embodiments of the present invention will be described in detail referring to attached drawings.

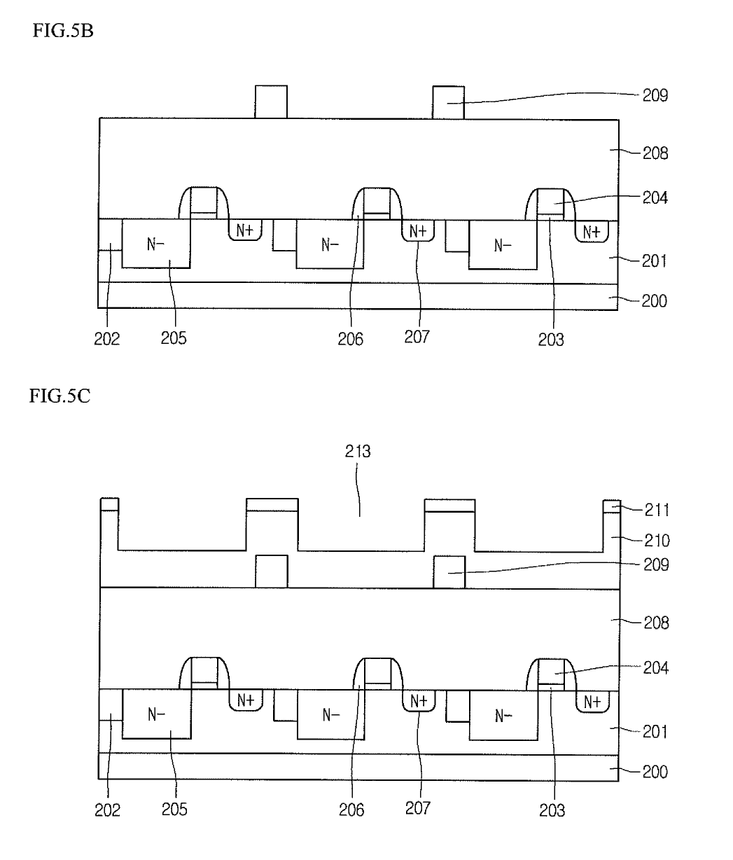

FIG. 4 is a cross-sectional view of a CMOS image sensor according to an embodiment of the present invention.

Referring to FIG. 4, a p− type epitaxial layer 201 can be grown on a p++ type semiconductor substrate 200, on which an isolation region and an active area (including a photodiode region and a transistor region) are defined. A field oxide layer 202 can be formed at the isolation region of the semiconductor substrate 200. A gate electrode 204 can be formed on the transistor region of the semiconductor substrate 200 with a gate insulating layer 203 formed therebetween.

In addition, n− type diffusion regions 205 can be formed on the photodiode region of the semiconductor substrate 200, and insulating layer sidewalls 206 can be formed at both side portions of the gate electrode 204.

A first interlayer dielectric 208 can be formed on the semiconductor substrate 200 including the gate electrode 204, and various metal wirings 209 can be formed on the first interlayer dielectric 208. In one embodiment the metal wirings 209 can be formed at a constant interval.

A second interlayer dielectric 210 can be formed on the semiconductor substrate 200 including the metal wirings 209, and a nitride layer 211 can be formed on the second interlayer dielectric 210.

After that, trenches having a predetermined depth can be formed by selectively removing the nitride layer 211 and the second interlayer dielectric 210 in regions corresponding to the n− type diffusion regions 205. Within the trenches, a color filter layer 213 of red (R), green (G) and blue (B) can be formed.

A plurality of microlenses 214 corresponding to each n− type diffusion region 205 can be formed on each color filter layer 213.

Here, reference number 207 represents a source and a drain impurity region of the transistor.

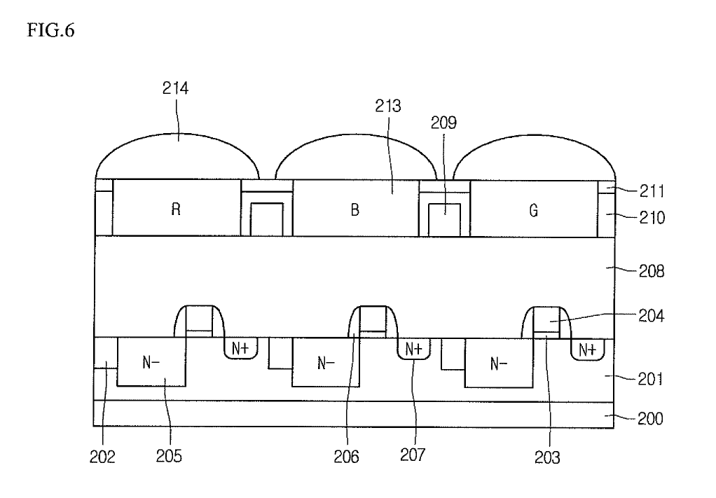

FIG. 6 is a cross-sectional view of a CMOS image sensor according to another preferred embodiment of the present invention.

For the CMOS image sensor illustrated in FIG. 6, the trench can be formed to a deeper depth than the CMOS image sensor illustrated in FIG. 4. In a further embodiment, the trench can be formed to expose a surface of the first interlayer dielectric 208, and each color filter layer 213 can be formed after the second interlayer dielectric 210 is removed and the first interlayer dielectric 208 is exposed.

That is, each color filter layer 213 can be formed on the first interlayer dielectric 208.

Accordingly, the distance between the microlens 214 and the photodiode region is reduced even further.

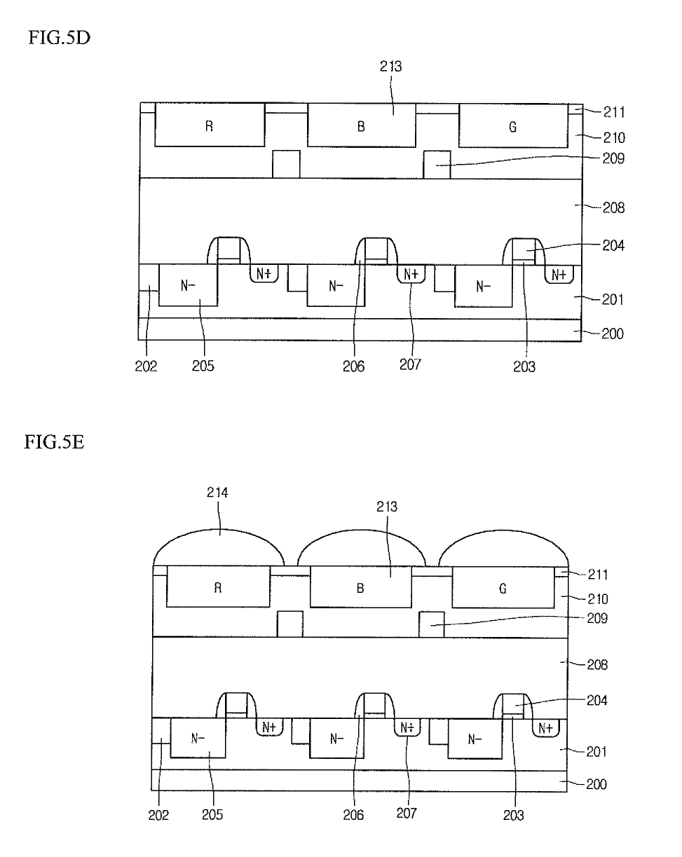

FIGS. 5A-5E are cross-sectional views for illustrating the method of manufacturing the CMOS image sensor according to an embodiment of the present invention.

Referring to FIG. 5A, a low concentration first conductive type (p− type) epitaxial layer 201 can be formed on a semiconductor substrate 200 such as a high concentration first conductive type (p++ type) polysilicon substrate by means of an epitaxial process.

The epitaxial layer 201 is formed to form a deep and wide depletion region at the photodiode area and to increase the capability of a low voltage photodiode to collect photo charges to further improve the photo-sensitivity.

A photodiode region, a transistor region and an isolation region can be defined on the semiconductor substrate 200, and an isolation layer 202 can be formed at the isolation region by using an STI process or a LOCOS process.

Then, a gate insulating layer 203 and a conductive layer (for example, a high concentration polysilicon layer) can be sequentially deposited on the epitaxial layer 201 on which the isolation layer 202 is formed. The conductive layer and the gate insulation layer 203 can be selectively removed to form a gate electrode 204 for each transistor.

Here, the gate insulating layer 203 can be formed by means of a thermal oxidation process or by a CVD method. In a further embodiment, a silicide layer can be further formed on the conductive layer to obtain a gate electrode.

In an embodiment, a thermal oxidation process can be carried out with respect to the surface of the gate electrode 204 and the semiconductor substrate 200 to form a thermal oxidation layer (not shown).

After that, low concentration second conductive type (n− type) impurity ions can be implanted onto the photodiode region of the semiconductor substrate 200 to form an n− type diffusion region 205.

Then, an insulating layer can be formed on the semiconductor substrate 200, and an etch back process can be performed to form an insulating layer sidewall 206 on both side portions of the gate electrode 204.

High concentration second conductive type (n+ type) impurity ions can be implanted onto the transistor region of the semiconductor substrate 200 to form a high concentration n+ type diffusion region 207.

A thermal treatment process (for example, a rapid thermal treatment process) can be performed to diffuse the impurity ions within the n− type diffusion region 205 and the n+ type diffusion region 207.

In a further embodiment, an n− type diffusion region (not shown) can be formed at the transistor region by implanting n− type implanting ions at a lower implantation energy than that at the n− type diffusion region 205 before forming the high n+ type diffusion region 207.

Referring to FIG. 5B, a first interlayer dielectric 208 can be formed on the semiconductor substrate 200.

In one embodiment, the first interlayer dielectric 208 can be formed as a silane-based insulating layer to recover dangling bonds within the semiconductor substrate 200 due to a large amount of hydrogen ions included therein and to effectively reduce a dark current.

A metal layer can be deposited on the first interlayer dielectric 208 and selectively etched by a photolithography process and an etching process to obtain various metal wirings 209.

Referring to FIG. 5C, a second interlayer dielectric 210 can be formed on the semiconductor substrate 200 including the metal wiring 209. In a specific embodiment, the second interlayer 210 can be formed to a thickness of about 3000-4000 Å.

Here, the second interlayer dielectric 210 can be formed by using USG (undoped silicate glass), PSG, BSG or BPSG.

A nitride layer 211 can be formed on the second interlayer dielectric 210. The nitride layer 211 can have a thickness of about 2000˜3000 Å.

The nitride layer 211 and the second interlayer dielectric 210 can be selectively removed in regions corresponding to the photodiode regions by performing a photo process and an etching process to form a plurality of trenches 212 having a predetermined depth from the surface.

Referring to FIG. 5D, a color filter layer 213, for example of red (R), blue (B) and green (G) can be formed within each trench through 212 corresponding to the n− type diffusion region 205.

Here, each color filter layer 213 for filtering light according to each wavelength region can be formed by coating dyeable photoresist on the semiconductor substrate including the trench 212, and performing an exposing and developing process.

Each color filter layer 213 may have a different thickness and so a planarization process such as a CMP (chemical mechanical polishing) process can be executed while setting the upper surface of the nitride layer 211 as an end point.

Referring to FIG. 5E, photoresist for a microlens used for improving the efficiency of the collection of the light at the n− type diffusion regions 205 can be coated on the semiconductor substrate 200 including each color filter layer 213.

Then, the photoresist can be selectively patterned by performing an exposing and developing process to form a microlens pattern.

At this time, when the photoresist is positive resist, the photo active compound of an initiator, which is an absorbing material of the photoresist, decomposes to improve transmittance. Therefore, a flood exposure is applied to decompose the photo active compound remaining in the microlens pattern.

Through the flood exposure for the microlens pattern, the transmittance is heightened and photo acid is generated to increase the flowability of the microlens.

The semiconductor substrate 200 on which the microlens pattern is formed can be placed on a hot plate (not shown), and can be heat treated at about 150˜300° C. to reflow the microlens pattern to form a convex shaped microlens 214.

The heat treated and reflowed microlens 214 can then be cooled. Here, the cooling treatment can be implemented by putting the semiconductor substrate 200 on a cooling plate.

As described above, the CMOS image sensor and the method of manufacturing the same according to the present invention can exhibit the following effects.

Each color filter layer can be formed within a trench such that forming a separate planarizing layer is not necessary. Accordingly, the focal distance between the microlens and the photodiode region is reduced to prevent the cross talk between neighboring pixels and to improve the sensitivity of the image sensor at the same time.

Although a preferred embodiment of the present invention has been described for illustrative purposes, those skilled in the art will appreciate that various modifications, additions and substitutions are possible, without departing from the scope and spirit of the invention as disclosed in the accompanying claims.

I claim:

1. A CMOS image sensor, comprising:
a semiconductor substrate including a plurality of photodiodes and a plurality of transistors;
a first interlayer dielectric formed on the semiconductor substrate;
a metal wiring and a second interlayer dielectric formed on the first interlayer dielectric;
a plurality of color filter layers formed within the second interlayer dielectric; and
a plurality of micro lenses formed on the plurality of color filter layers.

2. The CMOS image sensor according to claim 1, wherein the plurality of color filter layers are formed in a trench formed at the second interlayer dielectric.

3. The CMOS image sensor according to claim 1, wherein a nitride layer is formed on the second interlayer dielectric between each of the plurality of color filter layers.

4. The CMOS image sensor according to claim 1, wherein the second interlayer dielectric is formed between each of the plurality of color filter layers.

5. A CMOS image sensor, comprising:
a semiconductor substrate including a plurality of photodiodes and a plurality of transistors;
a first interlayer dielectric formed on a the semiconductor substrate;
a metal wiring, a plurality of color filter layers and a second interlayer dielectric formed on the first interlayer dielectric; and
a plurality of micro lenses formed on the plurality of color filter layers.

6. The CMOS image sensor according to claim 5, wherein the plurality of color filter layers are formed in a trench formed at the second interlayer dielectric.

7. The CMOS image sensor according to claim 5, wherein a nitride layer is formed on the second interlayer dielectric between each of the plurality of color filter layers.

8. The CMOS image sensor according to claim 5, wherein the second interlayer dielectric is formed between each of the plurality of color filter layers.

9. The CMOS image sensor according to claim 5, wherein each of the plurality of color filter layers are formed directly on the first interlayer dielectric.

10. The CMOS image sensor according to claim 5, wherein a metal wiring is formed between the plurality of color filter layers.

11. A method of manufacturing a CMOS image sensor, comprising:
forming a plurality of photodiodes and a plurality of transistors on a semiconductor substrate;
forming a first interlayer dielectric on the semiconductor substrate including the plurality of the photodiodes and the plurality of the transistors;
forming a metal wiring on the first interlayer dielectric;
forming a second interlayer dielectric on the first interlayer dielectric and the metal wiring;
forming a trench on the second interlayer dielectric;
forming a plurality of color filter layers in the trench; and
forming a plurality of micro lenses on the plurality of the color filter layers.

12. The method according to claim 11, further comprising forming a nitride layer on the second interlayer dielectric.

13. The method according to claim 12, wherein the nitride layer is etched during forming a trench on the second interlayer dielectric.

14. The method according to claim 11, wherein the second interlayer dielectric is formed between each of the plurality color filter layers.

15. The method according to claim 11, wherein the plurality of color filter layers are formed directly on the first interlayer dielectric.

16. The method according to claim 11, wherein the metal wiring is formed between the plurality of color filter layers.
